(19) United States
(12) Patent Application Publication
(10) Pub. No.: US 2019/0230912 A1
(43) Pub. Date: Aug. 1, 2019

(54) DETECTION DEVICE FOR DETECTING FISHING DEVICE ENTERING WATER AND METHOD THEREOF

(71) Applicant: Chih-Yuan HUANG, Kaohsiung City (TW)

(72) Inventor: Chih-Yuan HUANG, Kaohsiung City (TW)

(21) Appl. No.: 16/263,906

(22) Filed: Jan. 31, 2019

Related U.S. Application Data
(60) Provisional application No. 62/624,807, filed on Feb. 1, 2018.

(51) Int. Cl. A01K 97/12; A01K 93/02; H03K 17/96; G06F 1/16

(52) U.S. Cl. CPC A01K 97/125; G06F 1/1656; H03K 17/962; A01K 93/02

(57) ABSTRACT

A detection device for detecting a fishing device entering water and a method thereof are provided. The detection device includes a waterproof housing, a circuit board, a capacitive sensing module, and a control unit. The capacitive sensing module and the control unit are disposed on the circuit board. The capacitive sensing module is disposed adjacent to an inside wall surface of the waterproof housing and senses a capacitance value. The control unit receives the capacitance value and when the control unit makes a determination, according to the capacitance value, that the fishing device has entered water, the control unit generates a control signal to activate a to-be-controlled device.

### CROSS-REFERENCE TO RELATED APPLICATION

This application claims priority to and the benefit of, pursuant to 35 U.S.C. § 119, U.S. provisional patent application Ser. No. 62/624,807 filed on Feb. 1, 2018, the disclosure of which is incorporated herein in its entirety by reference.

### BACKGROUND OF THE INVENTION

### 1. Field of the Invention

The present invention relates to a fishing device, more particularly to a detection device for detecting a fishing device entering water, and a method thereof.

### 2. Description of the Related Art

In recent years, capacitive touch technology has been developed, which can detect a change in capacitance value of the capacitive sensor caused by human contact, and is commonly used in electronics or home appliances. In addition to being able to determine whether an approaching object is a finger or other tool, capacitive touch technology can also judge other materials with different dielectric coefficients.

As shown in FIG. 1, the conventional method for detecting a fishing device entering water usually uses two probes A and B to detect resistances of air and water, and then determine whether fishing device enters water according to the use characteristics of the smaller resistance of water. However, the protruded probes A and B may possibly damage the structure of the fishing device and may cause waterproof protection failure. Furthermore, a water stain on the surface of the fishing device is also easy to cause misjudgment.

### SUMMARY OF THE INVENTION

An objective of the present invention is to provide a detection device for detecting a fishing device entering water and a method thereof to solve the above-described problems.

In order to achieve the objective, the present invention provides a detection device for detecting a fishing device entering water. The detection device includes a waterproof housing, a circuit board, a capacitive sensing module, and a control unit. The circuit board is disposed inside the waterproof housing. The capacitive sensing module is disposed on the circuit board and adjacent to an inside wall surface of the waterproof housing to sense a capacitance value. The control unit is electrically connected to the capacitive sensing module and configured to receive the capacitance value, as well as determine whether the fishing device has entered water according to the capacitance value. When the control unit determines that the fishing device has entered water, the control unit generates a control signal to activate a to-be-controlled device.

Preferably, the capacitive sensing module includes a capacitive sensing unit and a capacitive sensing conversion unit electrically connected to the capacitive sensing unit, the capacitive sensing unit is disposed adjacent to the inside wall surface of the waterproof housing, and the capacitive sensing conversion unit obtains the capacitance value sensed by the capacitive sensing unit.

Preferably, the capacitive sensing unit contacts the inside wall surface of the waterproof housing.

Preferably, the circuit board is perpendicular to the inside wall surface of the waterproof housing, or the circuit board is parallel with the inside wall surface of the waterproof housing.

Preferably, the to-be-controlled device is a light-emitting unit, a motor, a buzzer, or any combination thereof.

In order to achieve the objective, the present invention provides a method for detecting a fishing device entering water, and the method includes the following steps: providing a waterproof housing; disposing a circuit board inside the waterproof housing, wherein the circuit board includes a capacitive sensing module and a control unit; disposing a capacitive sensing module adjacent to an inside wall surface of the waterproof housing to sense a capacitance value; using a control unit to receive the capacitance value and determine whether the fishing device has entered water according to the capacitance value; and generating a control signal to activate a to-be-controlled device when the control unit determines that the fishing device has entered water.

Preferably, the capacitive sensing module includes a capacitive sensing unit and a capacitive sensing conversion unit electrically connected to the capacitive sensing unit, and the method further includes: disposing the capacitive sensing unit adjacent to the inside wall surface of the waterproof housing; and using the capacitive sensing conversion unit to obtain the capacitance value sensed by the capacitive sensing unit.

Preferably, the capacitive sensing unit contacts the inside wall surface of the waterproof housing.

Preferably, the circuit board is perpendicular to the inside wall surface of the waterproof housing, or the circuit board is parallel with the inside wall surface of the waterproof housing.

Preferably, the to-be-controlled device is a light-emitting unit, a motor, a buzzer, or any combination thereof.

In brief, the detection device for detecting a fishing device entering water and method of the present invention can keep a waterproof structure for the fishing device, and the sensor built inside the structure of the detection device can sense and clearly determine whether the fishing device has entered water.

### DESCRIPTION OF THE DRAWINGS

The structure, operating principle and effects of the present invention will be described in detail by way of various embodiments which are illustrated in the accompanying drawings.

FIG. 1 is a schematic view of conventional art.

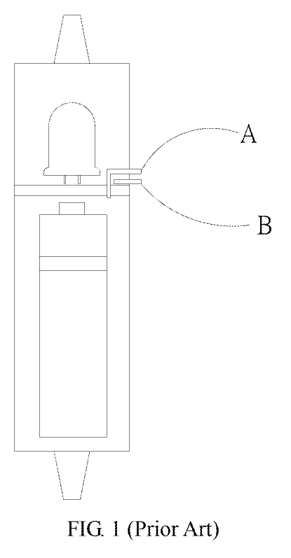

FIG. 2 is a block diagram of a detection device for detecting a fishing device entering water according to the present invention.

FIG. 3 is a schematic view of a detection device for detecting a fishing device entering water according to the present invention.

FIG. 4 is a first schematic view of a first embodiment of a detection device for detecting a fishing device entering water according to the present invention.

FIG. 5 is a second schematic view of a first embodiment of a detection device for detecting a fishing device entering water according to the present invention.

FIG. 6 is a schematic view of a second embodiment of a detection device for detecting a fishing device entering water according to the present invention.

FIG. 7 is a schematic view of a third embodiment of a detection device for detecting a fishing device entering water, according to the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. It is to be acknowledged that these embodiments are exemplary implementations and are not to be construed as limiting the scope of the present invention in any way. Further modifications to the disclosed embodiments, as well as other embodiments, are also included within the scope of the appended claims. These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts.

It is to be acknowledged that although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the word “comprise” and variations such as “comprises” or “comprising”, will be acknowledged to imply the inclusion of stated elements but not the exclusion of any other elements.

The present invention relates to a detection device for detecting a fishing device entering water and method of the present invention. The detection device uses a capacitive sensing circuit, which is built inside the underwater fishing device for sensing so that the circuit inside the fishing device is completely under waterproof protection and can detect whether the fishing device has entered water so as to further turn on or off some functions.

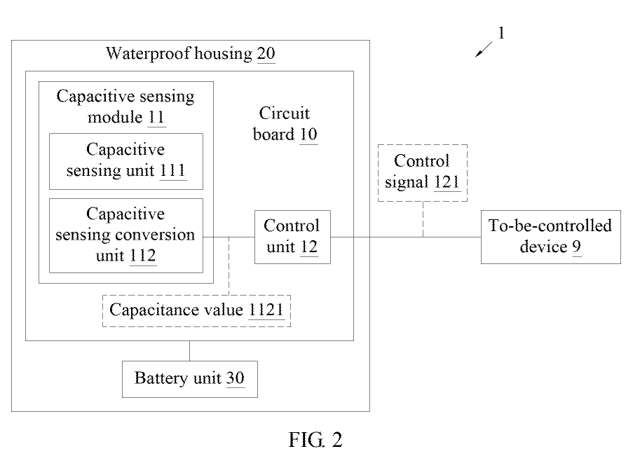

Please refer to FIG. 2, which is a block diagram of a detection device for detecting a fishing device entering water according to the present invention.

As shown in figure, the detection device 1 for detecting a fishing device entering water includes a circuit board 10, a capacitive sensing module 11, a control unit 12, and a waterproof housing 20. The circuit board 10 is disposed inside the waterproof housing 20. The capacitive sensing module 11 and the control unit 12 are disposed on the circuit board 10. The capacitive sensing module 11 is disposed adjacent to an inside wall surface of the waterproof housing 20 to sense a capacitance value 1121. The control unit 12 is electrically connected to the capacitive sensing module 11 and configured to receive the capacitance value 1121, and then determine whether the fishing device has entered water according to the capacitance value 1121. When the control unit 12 has determined that the fishing device has entered water, the control unit 12 generates a control signal 121 to activate a to-be-controlled device 9. In an embodiment, the to-be-controlled device 9 can be a light-emitting unit, a motor, a buzzer, or any combination thereof.

The above operation of determining whether the fishing device has entered water, for example, when the detection device 1 for detecting a fishing device entering water is applied as an underwater fishing lamp or the fish-like lure, the detection device 1 can determine whether the fishing device is in water. When the detection device 1 is applied as the underwater fishing lamp, and if the detection device 1 determines that the fishing device is in water, the control unit 12 controls the to-be-controlled device 9, such as a light-emitting unit, to emit light. In an embodiment of the present invention, when the detection device 1 is applied as the fish-like lure, and the detection device 1 determines that the fishing device is in water, the control unit 12 controls the to-be-controlled device 9, such as a motor or a buzzer, to operate. When the detection device 1 has determined that the fishing device is not in water, the control unit 12 controls the to-be-controlled device 9 to stop operating.

In a further embodiment of the present invention, the detection device for detecting the fishing device entering water 1 can also be a device which is disposed in or connected to the fishing device, and can be placed in water together with the fishing device. At this time, the control unit 12 controls the to-be-controlled device 9, such as wireless transmitter, to notify the relevant personnel that the fishing device has entered water. The connection between the control unit 12 and the to-be-controlled device 9 can be wired connection or wireless connection, and the manner of connection can be adjusted according to practical demand.

In yet another embodiment of the present invention, the capacitive sensing module 11 can include a capacitive sensing unit 111 and a capacitive sensing conversion unit 112 electrically connected to the capacitive sensing unit 111. The capacitive sensing unit 111 is adjacent to the inside wall surface of the waterproof housing 20. Preferably, the capacitive sensing unit 111 can contact or attach with an inside wall surface of the waterproof housing 20. The capacitive sensing conversion unit 112 can obtain the capacitance value 1121 sensed by the capacitive sensing unit 111, and the control unit 12 can calculate and determine, according to the capacitance value 1121, whether the fishing device is in water.

It is worth noting that the detection device 1 for detecting a fishing device entering water includes a battery unit 30 which can be a disposable battery or a rechargeable battery. The battery unit 30 can provide power to the detection device 1, or even provide power required for the to-be-controlled device 9 to operate.

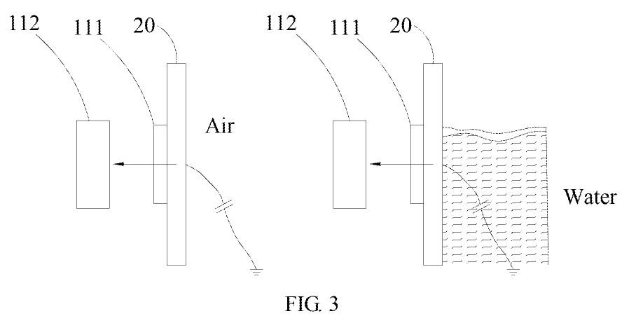

Please refer to FIG. 3 with reference to below equations,

$$Cs = Cair = ɛ \frac{A}{d}$$

$$Cs = Cwater = ɛ \frac{A}{d}$$

wherein C_{S} is a capacitance value, ε is a dielectric constant, A is an area, and d is a distance.

The dielectric constant ε of air is 1.00053, the dielectric constant of water is 78.5, and a distance d from the capacitive sensing module 11 to the outside and the area A of the capacitive sensing module 11 has not changed. Therefore, the detection device 1 can determines whether the fishing device has been placed in water according to the capacitance value.

Compared to the prior art, the detection device 1 of the present invention can maintain the complete waterproof structure of the fishing device and determine whether the fishing device has entered the water according to the capacitive sensing module 11 built inside the waterproof structure and the control unit 12 calculating and comparing the sensed capacitance value 1121. The waterproof protection structure of the detection device 1 of the present invention neither is easily damaged or broken by corrosion or the like, nor misjudge because of water stains on the surface of the fishing device.

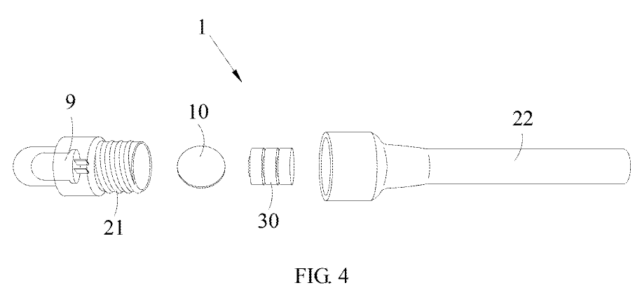

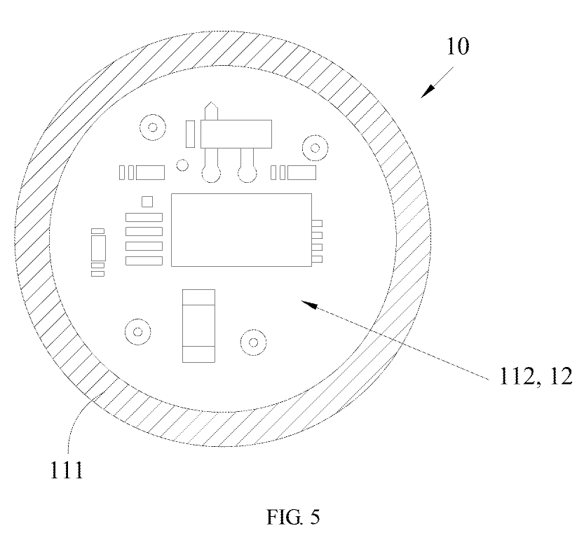

Please refer to FIGS. 4 and 5, which are a first schematic view and a second schematic view of a first embodiment of a detection device of detecting fishing device entering water according to the present invention, respectively.

As shown in figure, in the present embodiment, the detecting device 1 is applied as the underwater fishing lamp for exemplary illustration. The waterproof housing 20 can include a first housing 21 and a second housing 22 which can be combined with each other. The first housing 21 and the second housing 22 can be combined by locking, bonding, or ultrasonic welding method. Furthermore, a waterproof washer can be disposed between the first housing 21 and second housing 22 to effectively prevent water from entering the interior of waterproof housing 20. The combination manner and waterproof protection manner of the first housing 21 and the second housing 22 are well known to those skilled in the art, and so the detailed descriptions are not repeated herein.

It is worth noting that as shown in FIG. 5, the circuit board 10 can be a printed circuit board or a flexible printed circuit board, and the capacitive sensing unit 111 can be formed on the circuit board 10 by an etching manner or other manner and electrically connected to the capacitive sensing conversion unit 112.

The circuit board 10 including the capacitive sensing module 11 and the control unit 12 can be installed inside the waterproof housing 20 of the fishing device under water, and the capacitive sensing unit 111 can be disposed close to the inside wall of the waterproof housing 20. The circuit board 10 including the capacitive sensing module 11 and the control unit 12 can be disposed in perpendicular to the inside wall of the waterproof housing 20 to enable the capacitive sensing conversion unit 12 to sense the capacitance value 1121 effectively. When the detection device 1 is in water, the control unit 12 can control the to-be-controlled device 9, such as a light-emitting unit, to emit light, thereby enabling the underwater fishing lamp to achieve the purpose of attracting fishes to approach.

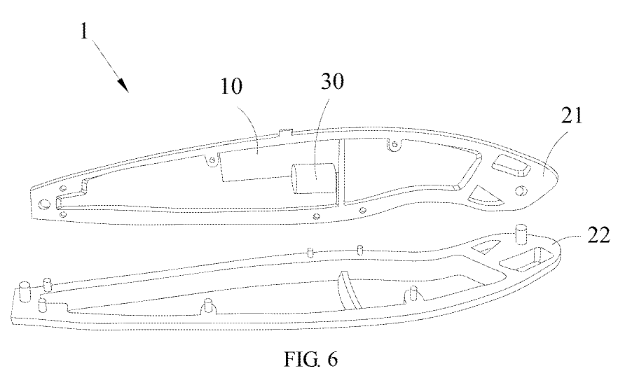

Please refer to FIG. 6, which is a schematic view of a second embodiment of a detection device for detecting fishing device entering water according to the present invention.

As shown in FIG. 6, in the present embodiment, the detecting device 1 is applied as the fish-like lure for exemplary illustration. Similarly, the waterproof housing 20 includes the first housing 21 and the second housing 22 which can be combined with each other. The first housing 21 and the second housing 22 can be combined through a locking manner, an engagement manner, a bonding manner, or an ultrasonic welding manner. A waterproof washer can be disposed between the first housing 21 and second housing 22 to effectively prevent water from entering the interior of waterproof housing 20.

The circuit board 10 including the capacitive sensing module 11 and the control unit 12 can be installed inside the waterproof housing 20 of the fishing device under water, and the capacitive sensing unit 111 can be disposed close to the inside wall of the waterproof housing 20. The circuit board 10 including the capacitive sensing module 11 and the control unit 12 can be disposed perpendicular to the inside wall of waterproof housing 20 to enable the capacitive sensing conversion unit to sense the capacitance value 1121 effectively. When the detection device 1 is in water, the control unit 12 can control the to-be-controlled device 9, such as a motor or a buzzer, to operate.

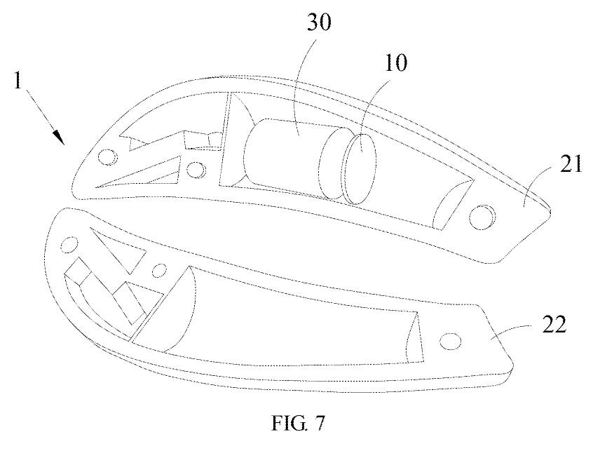

Please refer to FIG. 7, which is a schematic view of a third embodiment of a detection device for detecting a fishing device entering water according to the present invention.

As shown in FIG. 7, in the present embodiment, the fish-like lure is taken as an example of the detection device 1 for exemplary illustration. Similarly, the waterproof housing 20 can include the first housing 21 and the second housing 22 which are combined with each other. The first housing 21 and the second housing 22 can be combined by locking manner, bonding manner, or ultrasonic welding method. A waterproof washer can be disposed between the first housing 21 and second housing 22 to effectively prevent water from entering the interior of waterproof housing 20.

The circuit board 10 including the capacitive sensing module 11 and the control unit 12 can be installed inside the waterproof housing 20 of the fishing device under water, and the capacitive sensing unit 111 can be disposed close to the inside wall of the waterproof housing 20. The circuit board 10 including the capacitive sensing module 11 and the control unit 12 can be disposed in parallel with the inside wall of the waterproof housing 20 to enable the capacitive sensing conversion unit to sense the capacitance value 1121 effectively. When the detection device 1 is in water, the control unit 12 starts operation of the to-be-controlled device 9, such as a motor or a buzzer, so as to enable the fish-like lure to move or make a sound.

It is worth noting that in the second and third embodiments described above, the battery unit 30, and the circuit board 10 including the capacitive sensing module 11 and the control unit 12 can be properly fixed inside the waterproof housing 20 by means of the proper structure or adhesion in the waterproof housing 20. The manner of proper structure or adhesion is a technical means well known to those of ordinary skill in the art, so the detailed description is not repeated herein.

It should be noted that the main concept of the present invention is that the capacitive sensing module 11 is disposed close to the inside wall surface of the waterproof housing 20. It is of no matter whether or not the capacitive sensing module 11 can be disposed in perpendicular to, or in parallel with, or obliquely on the inside wall surface of the waterproof housing 20. Moreover, it is of no matter whether or not the capacitive sensing module 11 is in contact with or spaced from the inside wall surface of the waterproof housing 20. The capacitive sensing unit 111 can sense and judge the difference between air and water; however, the present invention is not limited to the above examples.

The present invention further provides a method for detecting a fishing device entering water, and the method includes steps S11 to S15. In step S11, the waterproof housing is provided. In step S12, circuit board is disposed inside the waterproof housing, and the circuit board includes the capacitive sensing module and the control unit. In step S13, the capacitive sensing module is disposed adjacent to the inside wall surface of the waterproof housing so as to sense the capacitance value. In step S14, the control unit receives the capacitance value, and determines whether the fishing device has entered water according to the capacitance value. In step S15, if the control unit determines that the fishing device has entered water, the control unit generates the control signal to activate the to-be-controlled device.

The detailed description of the method for detecting the fishing device entering water can refer to the description of the above detection device of detecting fishing device entering water, so the detailed description is not repeated herein.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A detection device for detecting a fishing device entering water, comprising:
a waterproof housing;
a circuit board disposed inside the waterproof housing;
a capacitive sensing module disposed on the circuit board and adjacent to an inside wall surface of the waterproof housing to sense a capacitance value; and
a control unit electrically connected to the capacitive sensing module and configured to receive the capacitance value and determine whether the fishing device has entered water according to the capacitance value, and when the control unit has determined that the fishing device has entered water, the control unit generates a control signal to activate a to-be-controlled device.

2. The detection device according to claim 1, wherein the capacitive sensing module comprises a capacitive sensing unit and a capacitive sensing conversion unit electrically connected to the capacitive sensing unit, the capacitive sensing unit is disposed adjacent to the inside wall surface of the waterproof housing, and the capacitive sensing conversion unit obtains the capacitance value sensed by the capacitive sensing unit.

3. The detection device according to claim 2, wherein the capacitive sensing unit contacts the inside wall surface of the waterproof housing.

4. The detection device according to claim 2, wherein the circuit board is perpendicular to the inside wall surface of the waterproof housing, or the circuit board is parallel with the inside wall surface of the waterproof housing.

5. The detection device according to claim 1, wherein the to-be-controlled device is a light-emitting unit, a motor, a buzzer, or any combination thereof.

6. A method for detecting a fishing device entering water, comprising,
providing a waterproof housing;
disposing a circuit board inside the waterproof housing, wherein the circuit board comprises a capacitive sensing module and a control unit;
disposing a capacitive sensing module adjacent to an inside wall surface of the waterproof housing to sense a capacitance value;
using a control unit to receive the capacitance value and determine whether the fishing device has entered water according to the capacitance value; and
generating a control signal to activate a to-be-controlled device when the control unit determines that the fishing device has entered water.

7. The method according to claim 6, wherein the capacitive sensing module comprises a capacitive sensing unit and a capacitive sensing conversion unit electrically connected to the capacitive sensing unit, and the method further comprises:
disposing the capacitive sensing unit adjacent to the inside wall surface of the waterproof housing; and
using the capacitive sensing conversion unit to obtain the capacitance value sensed by the capacitive sensing unit.

8. The method according to claim 7, wherein the capacitive sensing unit contacts the inside wall surface of the waterproof housing.

9. The method according to claim 7, wherein the circuit board is perpendicular to the inside wall surface of the waterproof housing, or the circuit board is parallel with the inside wall surface of the waterproof housing.

10. The method according to claim 6, wherein the to-be-controlled device is a light-emitting unit, a motor, a buzzer, or any combination thereof.
